(19) United States
(12) Patent Application Publication
(10) Pub. No.: US 2006/0124832 A1
(43) Pub. Date: Jun. 15, 2006

(54) Wide dynamic range photodetector

(75) Inventors: Eric S. Harmon, Norfolk, MA (US); David B. Salzman, Chevey Chase, MD (US)

Correspondence Address: David Garrod, Esq., Goodwin Procter LLP, 599 Lexington Avenue, New York, NY, 10022, US

(73) Assignee: LightSpin Technologies, Inc., Chevy Chase, MD (US)

(21) Appl. No.: 11/234,958

(22) Filed: Sep. 26, 2005

Related U.S. Application Data
(60) Provisional application No. 60/613,321, filed on Sep. 27, 2004.

(51) Int. Cl. H01J 40/14; H01L 31/00

(52) U.S. Cl. 250/214 R; 250/214.1

(57) ABSTRACT

The invention provides a means of enhancing the dynamic range and linearity of photodetectors and imaging photodetector arrays. This is achieved by combining Geiger mode avalanche photodiodes (APDs) capable of high efficiency detection of single photons and conventional semiconductor photodetectors with poor noise floors to simultaneously achieve high efficiency detection of single photons and a wide dynamic range.

### CROSS-REFERENCE TO RELATED APPLICATION

This application claims priority from the U.S. Provisional Patent Application No. 60/613,321 filed Sep. 27, 2004.

### FIELD OF THE INVENTION

This invention relates generally to the fields of solid state physics and electronics, more particularly to the design and fabrication of semiconductor photodetectors and photodetector arrays, and still more particularly to the design, fabrication and structure of elements of photodetectors, and arrays thereof, achieving wide dynamic range and single-photon sensitivity.

### BACKGROUND OF THE INVENTION AND LIMITATIONS OF THE PRIOR ART

For many optical detection applications, it is desirable to achieve a wide dynamic range and maximum sensitivity simultaneously. It is possible for certain detectors to detect single photons with high detection efficiency, but many of the technologies capable of detecting single photons at room temperature (e.g. Geiger mode avalanche photodiodes (APDs), vacuum tube devices, and other devices), have limited dynamic range. For example, Geiger mode APDs can detect single photons, but have binary dynamic range because each detection event has an associated dead time where the detector is unable to detect subsequent photons. Furthermore, the output signal generated in a Geiger mode APD is nearly identical regardless of the number of photons triggering the event. This means that the output signal for 1 photon is nearly identical to the output signal for n photons, making it impossible to distinguish between detection events triggered by 1 photon, 2 photons, or n-photons.

Some alternatives have been developed to allow increased dynamic range using single-photon detectors such as Geiger APDs or vacuum tube devices. For example, spreading the input optical signal among a large number of Geiger elements (see, for example P. BUZHAN, et al., “Silicon photomultiplier and its possible applications,” Nuclear Instruments and Methods in Physics Research A, 502, pp. 48-52, 2003, V. GOLOVIN and V. SAVELIEV, “Novel type of avalanche photodetector with Geiger mode operation,” Nuclear Instruments and Methods in Physics Research A, v. 518, pp. 560-564, 2004, and E. S. HARMON, et al., “Solid State Micro Channel Plate Photodetector,” U.S. Pat. App. No. US 2004/0245592 filed 1 May 2004, priority date 1 May 2003), allows the instantaneous dynamic range to be as large as the number of parallel Geiger elements available to detect incident photons. For example, the silicon photomultiplier (SiPM) has demonstrated 2,000 Geiger elements in a 1 mm² active area, allowing about 11 bits of instantaneous dynamic range to be achieved. Similarly, the micro-channel plate (MCP) photomultiplier tube has a large number of channels, each of which is capable of detecting a single photons. Since the channel spacing in a MCP can be as small as 5 um, achieving about 5,000 elements per mm², it offers more than 12 bits of instantaneous dynamic range per square millimeter.

Many prior art approaches exist for segmenting imaging arrays into pixels of different wavelength selectivity, resolution, or photosensitivity. For instance, the human eye concentrates “cone” cells at high resolution in the central “fovea” region of the retina and primarily “rod” cells with lower spatial resolution further out. Cone cells are selective to red, green, and blue light. Rod cells see black & white, but with superior low light photosensitivity.

The present invention differs from these in addressing the dynamic range of photosensitivity by extending it down to the ultimate level of single photons. For certain applications, it is valuable to achieve significantly higher dynamic range to discern dim objects amidst the clutter of bright ones. For example, it may be necessary to achieve a 14 bit dynamic range in a 100 μm×100 μm pixel, which is equivalent to 20 bits of dynamic range per mm², and would require a single-photon detector spacing of less than 0.1 μm, which is not feasible with most single-photon detector approaches.

### BRIEF DESCRIPTION OF THE INVENTION

To achieve high dynamic range while retaining high sensitivity to single photons, the invention combines wide dynamic range detectors such as PIN photodiodes, APDs, metal-semiconductor-metal (MSM) detectors, photocondutive detectors, or CCD detectors with single-photon detectors such as Geiger mode APDs, or solid-state microchannel plate (SSMCP) arrays of Geiger mode APDs. By splitting the input optical signal such that a portion of the signal illuminates the single-photon detector and another portion illuminates a wide dynamic range detector, a very wide dynamic range can be achieved, while retaining the capability to detect single photons with high detection efficiency.

### OBJECTS OF THE INVENTIONS

One object of the invention is to combine single-photon sensitive, limited dynamic range photodetector elements with wide dynamic range, non-single-photon detector elements, to extend the sensitivity of the wide dynamic range detector to single-photons. In general, the number and configuration of the single-photon detector elements and wide dynamic range elements can be different in both number and size.

Another object of the invention is to achieve this combination by inserting the wide dynamic range detector elements into the dead space between the single-photon sensitive elements, turning this dead space as a useful detector element.

Another object of the invention is to divide the light between the single-photon sensitive elements and the wide dynamic range elements, with the ratio of the light absorbed in the two elements designed to optimize dynamic range, linearity, or both.

Another object of the invention is to divide the detection elements into an imaging array. Thus, the single-photon sensitive elements, the wide dynamic range elements, or both may form imaging arrays, allowing wide dynamic range to be achieved in imaging applications.

A further object of the invention is to employ photodetector elements with different wavelength selectivities in an array containing abutting pixels with analog and Geiger responses.

### BRIEF DESCRIPTION OF THE FIGURES

FIG. 1A shows a prior art imaging array in top-view comprising two overlapped arrays of a two pixel types. The pixels might be selective to two different wavelength bands, though no such prior art array combines an array of single-photon sensitive Geiger pixels with an array of wide dynamic range pixels.

FIG. 1B shows a prior art foveated imaging array in top-view concentrating high resolution pixels centrally and lower resolution pixels more peripherally.

FIG. 2A shows an embodiment of the present invention in top-view, wherein single-photon sensitive pixels and wide dynamic range pixels are distributed over an area in interpenetrating imaging arrays to provide both imaging with single-photon sensitivity and imaging with wide dynamic range at every pixel.

FIG. 2B shows a vertical distribution of detectors in side-view, with the single-photon sensitive pixel layer fabricated on one side of a substrate and the wide dynamic range pixel layer fabricated on the other side of the substrate.

FIG. 2C shows a vertical distribution of detectors in side-view, with both the single-photon sensitive pixel layer and the wide dynamic range pixel layer fabricated on the same side of the wafer, and the wide dynamic range detector layer on top of the single-photon detector layer.

FIG. 2D shows a vertical distribution of detectors in side-view, with both the single-photon sensitive pixel layer and the wide dynamic range pixel layer fabricated on the same side of the wafer, with the single-photon detector layer on top of the wide dynamic range detector layer.

FIG. 2E shows in side-view how the dead space between single-photon sensitive detector elements can be recovered by using a vertical distribution of detector elements, where the underlying wide dynamic range detectors capture light incident on the dead space between the overlying single-photon detector element.

FIG. 2F shows another approach in side view for recovering the dead space between single-photon sensitive detector elements when backside illumination is used.

FIG. 2G shows in side-view how the layer structure of FIG. 2C can be used to fabricate an imaging array comprising single-photon detector elements on one side of the wafer and a single element, position sensitive, wide dynamic range detector on the other side of the wafer.

FIG. 2H shows in side-view how the layer structure of FIG. 2D can be fabricated to achieve individual connections to every single-photon detector element and every wide dynamic range detector element.

FIG. 2I shows schematically how an optical element may be used to divide the incident light between separate detector planes, with one detector plane consisting of single-photon sensitive elements, and the other detector plane consisting of wide dynamic range elements.

FIG. 3A shows a lateral distribution of single-photon sensitive detector elements with wide dynamic range elements fabricated in the dead space regions.

FIG. 3B shows a lateral distribution of single-photon sensitive detector elements with a single, position sensitive wide dynamic range fabricated to encompass nearly all of the dead space between pixels.

FIG. 4A shows one arrangement of the readout circuitry, where the output of each detector element is digitized and then combined with a signal processor to provide a high linearity, wide dynamic range output with single-photon sensitivity.

FIG. 4B shows another arrangement of the readout circuitry where the output of the single-photon sensitive detector element is used to gate the output of the wide dynamic range detector element, reducing the readout noise of the amplifier used for the wide dynamic range elements.

### DETAILED DESCRIPTION OF THE FIGURES

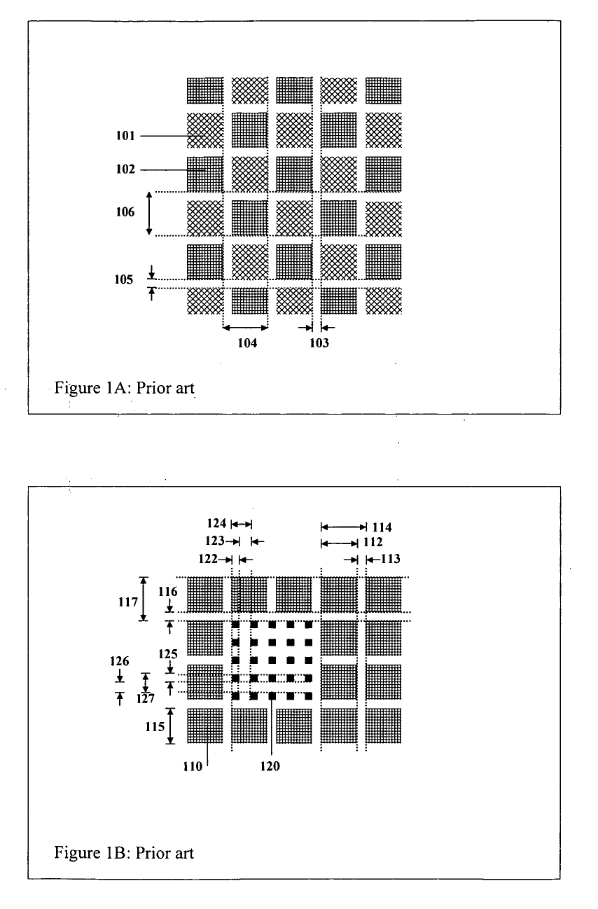

Reference is now made to FIG. 1A, showing a prior art imaging array comprising overlapped arrays of a two pixel types, indicated and cross-hatched respectively as 101 and 102. The horizontal center-to-center pitch is indicated by 104 and the vertical center-to-center pitch by 106. The dead areas between adjacent pixels are indicated by 103 and 105. An important prior art arrangement in accordance with the figure is selective to three different colors, repeating one of them to make a 4-element array for camera/imaging chips. It is well-known to those in the art that the beam of light intercepted by a cluster of pixels in such an imaging array must be shared among multiple elements. This constraint makes any pitch below the diffraction-limited focus of the beam irradiating each cluster equivalent to the larger diffraction limit length scale, if one ignores the detailed shape of Airy disks and any near-field effects. It also sets the spatial resolution of the imaging array in practice.

We note that there is no prior art array combining an array of single-photon sensitive Geiger pixels with an overlapping array of wide dynamic range pixels. That is because the technology for room-temperature single-photon sensitive pixels has heretofore been process-incompatible with wide dynamic range pixels.

Reference is now made to FIG. 1B, showing a prior art foveated imaging array concentrating low resolution pixels 110 peripherally and higher resolution pixels 120 centrally. The figure indicates width 112, horizontal dead area 113, center-to-center horizontal pitch 114, height 115, vertical dead area 116, and center-to-center vertical pitch 117 for the first style of pixels 110. The figure also indicates width 122, horizontal dead area 123, center-to-center horizontal pitch 124, height 125, vertical dead area 126, and center-to-center vertical pitch 127 for the second style of pixels 120. Such arrays imitate the human eye, and are commonly used for applications like machine vision and tracking moving objects.

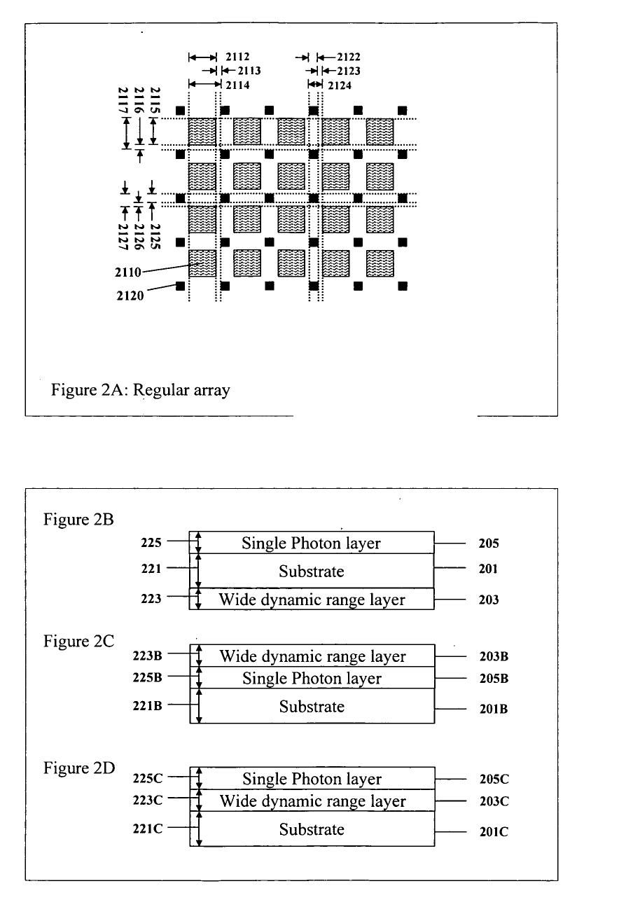

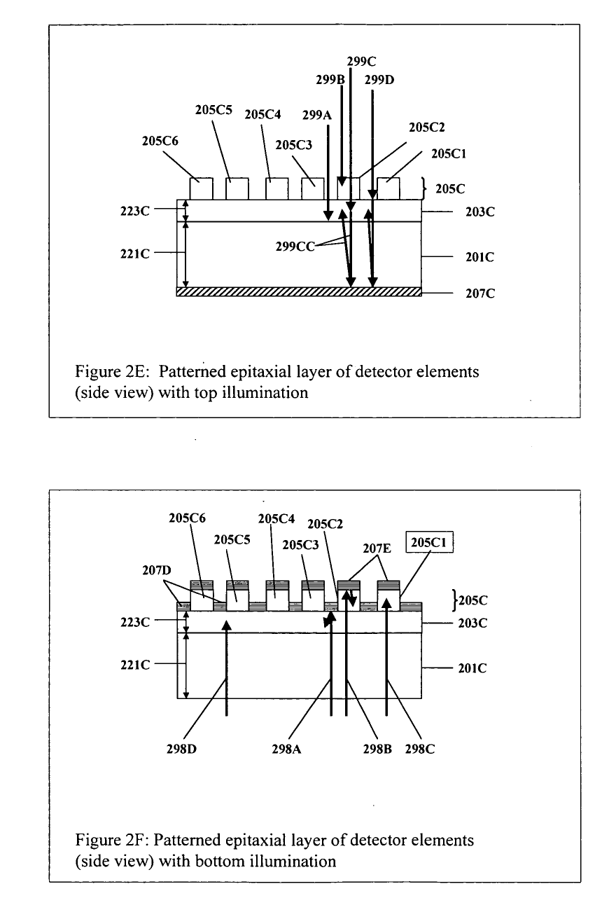

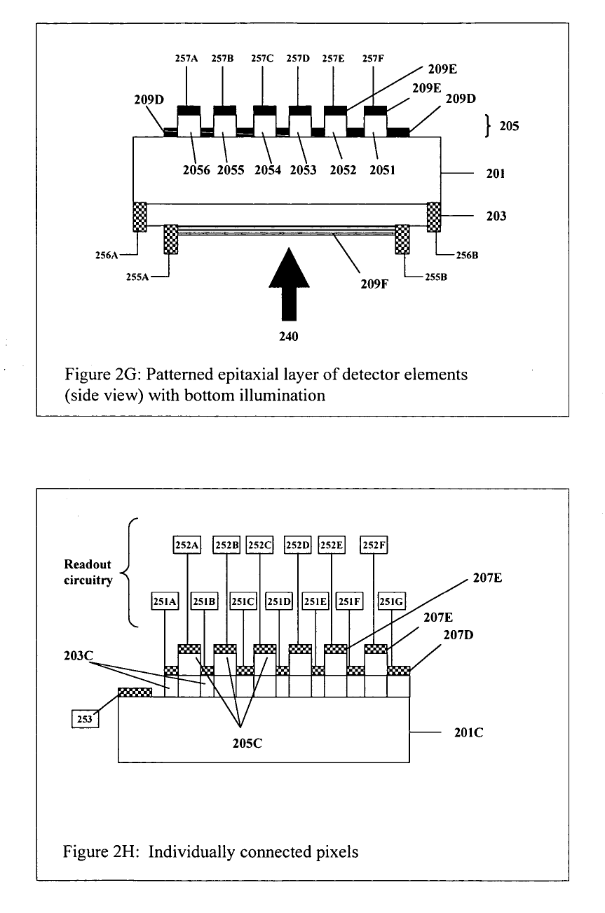

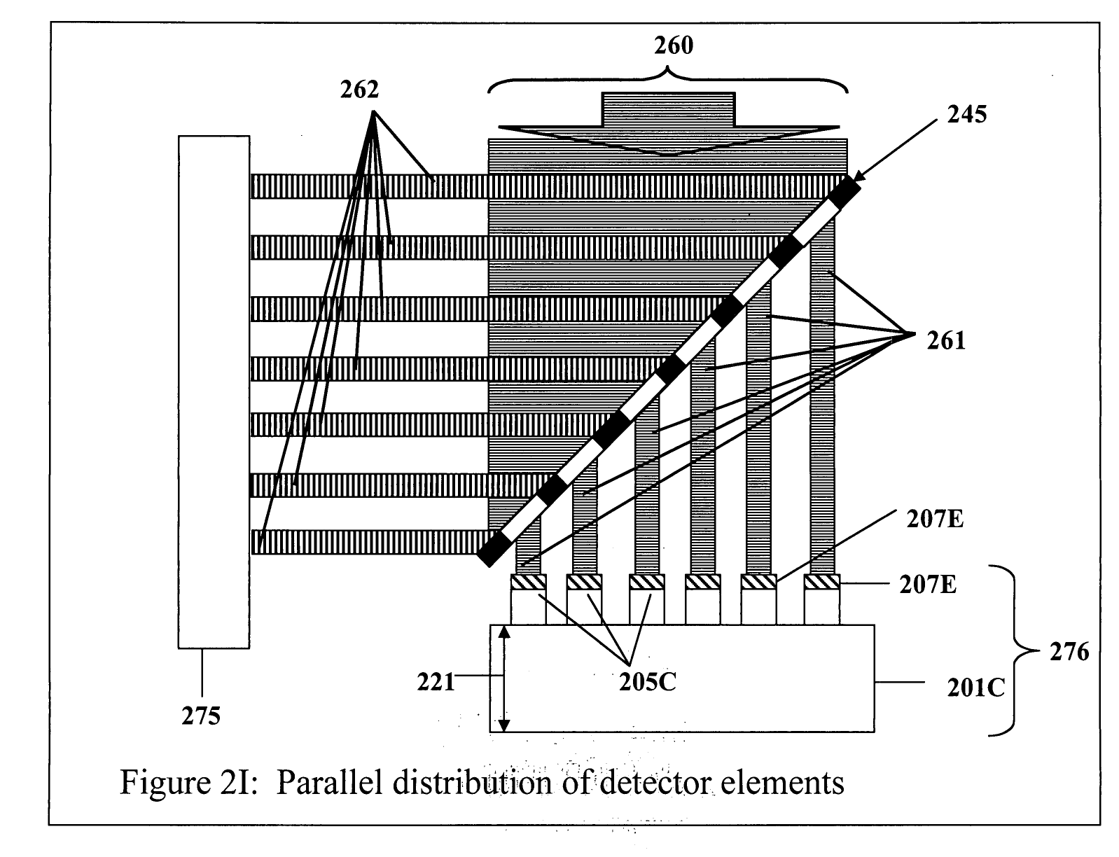

Reference is now made to FIG. 2A, depicting a distribution of single-photon sensitive detector elements 2110 and wide dynamic range detector elements 2120. Advantageously, detector elements 2110 form a single-photon sensitive imaging array, as do wide dynamic range detector elements 2120, and the arrays interpenetrate. Advantageously, the arrays of the two kinds of detector elements 2110 and 2120 do not occupy the same space, so the wide dynamic range photodetector elements 2120 can exploit the dead space between elements of 2110. The grid of single-photon sensitive photodetector elements 2110 has a center-to-center pitch given by the sum of the distances 2114+2124 horizontally and 2117+2127 vertically. Distance 2114 is defined by the width 2112 of the photodetector elements plus the width of the gutter 2113. Distance 2117 is defined by the height 2115 of the photodetector elements plus the height of the gutter 2116. Distance 2124 is defined by the width 2122 of the photodetector elements plus the width of the gutter 2123. Distance 2127 is defined by the height 2125 of the photodetector elements plus the height of the gutter 2126. The gutters 2123, 2113, 2116 and 2126 are described distinctly to keep track of different options and underscore that the pixels need not be square, nor even rectangular, nor the same size as the other type, nor on a rectangular grid, nor even on a strictly regular grid. Advantageously, the gutters will be as small as allowed by processing and cross-talk minimization considerations.

The optimum absolute and relative sizes of the two pixel types may depend in complicated ways upon details of noise floors, the influences of pixel area and perimeter on noise and signal, time constants, gutter sizes, lithographic feature size, and other considerations. For example, consider a system where 90% of the incident optical signal illuminates a solid state microchannel plate (SSMCP) array of 1024 Geiger mode APDs connected in parallel, and the remaining 10% of the incident optical signal illuminates a wide dynamic range array of PIN photo diodes. The SSMCP array would provide a dynamic range up 10 bits. If the noise floor of a PIN photodiode is good (e.g. about 100 photons/pulse) and it occupies only 10% of the total detector area, then it can detect signals down to 1000 photons above the noise floor instantaneously (i.e. without resorting to sampling or gating techniques). A PIN photodiode saturating at 1 mA of current would tolerate approximately 6×10⁷ photons/ns (assuming 10% fill factor and 100% quantum efficiency), providing an instantaneous dynamic range of about 6×10⁷: 1, or nearly 26 bits.

Where high linearity is needed as well, it becomes prudent to correct the single-photon detector for saturation effects. For instance, precision to 1% can be preserved when the fraction of simultaneous photons per pixel exceeds about 10% of the total number of photons (e.g. more than about 100 photons/pulse in the preceding example) even though the single-photon detector array begins to saturate due to the probability of two-or-more photons being simultaneously incident on single sub-pixel becomes appreciable. Note that the output of each single-photon sensitive detector pixel is indifferent to 1 versus many incident photons. A suitable look-up table can then be used to improve linearity between about 100 incident photons and about 10,000 photons, where the accuracy of the wide dynamic range photo detector takes over to provide sufficient linearity.

Note that the wide dynamic range photodetector elements need not have a linear response. A logarithmic response may be particularly useful in capturing a wide dynamic range. In any case, an algorithm or lookup table can be used to correct (process) the received signal from both pixel types into a single, linear representation or other useful encoding.

In addition to giving pixels with wide dynamic range sensitivity down to single photons, the invention presents a number of advantages:
In pulsed applications, a Geiger detector generally exhibits excellent timing resolution, allowing the arrival time of photons to be known with high precision. Relying on a single-photon sensitive pixel for timing information often allows a wide dynamic range pixel to have lower bandwidth, and consequently low-frequency circuitry with lower noise and lower power dissipation to be used to analyze the pulse amplitude received on the wide dynamic range pixel.
In pulsed applications, a single-photon sensitive pixel can be used to provide a gating signal for its wide dynamic range pixel, further reducing the noise of the readout circuitry for the latter pixel.
Many single-photon detectors require appreciable space between pixels to be “dead” in order to suppress cross-talk and after-pulsing. In some cases, it will be practical to fit the wide dynamic range detector elements into the dead space, increasing dynamic range without sacrificing single-photon sensitive pixel area or performance.
The area of the single-photon detector(s) can be different from the area of the wide dynamic range detector(s). This allows performance, sensitivity, and bandwidth to be optimized separately and balanced.
The number of imaging pixels can be different between a single-photon sensitive imaging array and the wide dynamic range imaging array. Two extreme examples follow: (1) The single-photon sensitive imaging array is suitable for high-resolution imaging, employing a large number of pixels (e.g. 1024×1024). The wide dynamic range detector comprises a single pixel, and is used to obtain only the approximate amplitude of the return pulse. (2) The single-photon sensitive device is used as a single device, providing a very high sensitivity detection of the return signal, but nearly no spatial resolution. The wide dynamic range detector is a multi-megapixel CCD camera, used to provide a range gated image of the return signal, at improved sensitivity and decreased noise.

Reference is now made to FIG. 2B, showing how a single-photon sensitive detector epitaxial layer 205 of thickness 225 is formed on one side of a transparent substrate 201 of thickness 221, and the wide dynamic range detector epitaxial layer 203 of thickness 223 is formed on the opposite side of the substrate 201. For a top-illuminated device, layer 205 must transmit a large enough fraction of the irradiant photon flux to substrate 201, and substrate 201 must absorb few enough of these photons, for a sufficient photon flux to reach layer 203 and produce an acceptable signal. Similarly, for a bottom-illuminated device, layer 203 must transmit a sufficient fraction of the incident photon flux to substrate 201, and substrate 201 to layer 205.

FIG. 2C shows a wide dynamic range detector layer 203B of thickness 223B formed on top of the single-photon sensitive detector layer 205B of thickness 225B, which has been formed on top of substrate 201B of thickness 221B. For a top-illuminated device, layer 203B must transmit enough of the incident photon flux for layer 205B to work. For a bottom-illuminated device, substrate 201B must absorb little enough of the irradiant photon flux for layers 205B and 203B to function.

FIG. 2D shows a single-photon sensitive detector layer 205C of thickness 225C formed on top of the wide dynamic range detector layer 203C of thickness 223C, which has been formed on top of substrate 201C of thickness 221C. For a top-illuminated device, layer 205C must transmit at least a small fraction of the incident photon flux to layer 203C. For a bottom-illuminated device, substrate 201C must exhibit low absorption of the incident photons so that a sufficient photon flux is incident on layer 203C, and layer 203C must transmit a substantial fraction of the incident photon flux to layer 205C.

FIG. 2E shows a single-photon sensitive detector layer 205C divided into an array of single-photon sensitive detector elements 205C1, 205C2, 205C3, 205C4, 205C5, and 205C6. Under top illumination, a photon flux (illustrated by independent paths 299A, 299B, 299C, and 299D) is incident as shown in the figure. Photon flux 299A is incident in the dead space between single-photon detector elements 205C2 and 205C3, so can be absorbed in the wide dynamic range detector layer 203C. Photon flux 299B is incident on single-photon detector element 205C2, where it is absorbed and detected with single-photon sensitivity. Flux 299C follows the same path but is not absorbed in 205C2, so represents the fraction transmitted to detector layer 203C, in which some of it is absorbed. A smaller fraction 299CC can be transmitted through layer 203C, through substrate 201C, reflected off of a back-mirror 207C, and redirected up through layer 201C into layer 203C, where it is either absorbed or transmitted further up to element 205C2, where it is either absorbed or lost out the top. Photon flux 299D represents fraction of light incident on the dead space between detector elements 205C1 and 205C2 but not absorbed in layer 203C, such that it transmits through layer 203C and substrate 201C, reflects off mirror 207C, transmits through layer 201C, and is again incident on layer 203C: in other words, double-pass absorption is supported. Appropriate design of layers 205C and 203C allows the ratio of photons absorbed in each layer to be controlled to achieve the desired linearity, dynamic range, and sensitivity.

FIG. 2F shows how single-photon detector layer 205C can be divided into an array of single-photon sensitive detector elements 205C1, 205C2, 205C3, 205C4, 205C5, and 205C6 for bottom illumination. Photon flux 298A is transmitted through substrate 201C, and is incident first on layer 203C. A fraction of photon flux 298A is transmitted through layer 203C, where it becomes incident on the dead space between pixels 205C2 and 205C3. Reflective layer 207D is used to reflect substantially all of photon flux 298A back into layer 203C where it may be absorbed and contribute to the photosensitivity of layer 203C. Photon flux 298B is transmitted through substrate 201C, and is incident first on layer 203C. A fraction of photon flux 298B is transmitted through layer 203C, where it becomes incident on pixel 205C2. A fraction of photon flux 298B is transmitted through pixel 205C2, where it becomes incident on top reflector 207E, which reflects substantially all of this flux back into pixel 205C2, where it may be absorbed and contribute to the photoresponse of pixel 205C2. Photon flux 298C is transmitted through substrate 201C and through layer 203C, where it is absorbed in pixel 205C1, contributing to the photoresponse of pixel 205C1. Photon flux 298D is transmitted through substrate 201C and into layer 203C, where it is absorbed and contributes to the photoresponse of layer 203C.

FIG. 2G shows the preferred embodiment of the invention. The incident photon flux 240 is incident from the bottom. Layer 209F is an optical coating designed to work in conjunction with metal contact layers 209D and 209E to maximize the absorption of photons in layers 203 and detector elements 2051, 2052, 2053, 2054, 2055, and 2056. The preferred embodiment is configured to report the position along a line (from left to right) of an incident irradiant spot as well as the intensity. The wide dynamic range detector array is formed in epitaxial layer 203 and configured as a single element position-sensitive detector such that a pair of electrical contacts at opposite ends can share the output current in proportion to the position of the centroid of the incident flux power. In the preferred embodiment, detector layer 203 forms a PIN photodetector structure, with contacts 255A and 255B contacting the p-type side of the device, and contacts 256A and 256B contacting the n-type side of the device. A small fraction of the incident light 240 is absorbed in layer 203, while the majority of the light is transmitted to the single-photon detector elements 2051, 2052, 2053, 2054, 2055, and 2056. In the preferred embodiment, the single-photon detector elements are solid state microchannel plate (SSMCP) detectors (see HARMON, et. al, “Solid State Micro Channel Plate Photodetector”, patent application 2004/0245592 filed 1 May 2004, priority date 1 May 2003), capable of detecting single photons and distinguishing the number of photons/pulse with a dynamic range determined by the number of sub-pixel elements in the SSMCP detector. As an example, each of the single-photon detector elements 2051, 2052, 2053, 2054, 2055, and 2056 could each consist of a SSMCP detector element with 100 sub-pixels per element, allowing a dynamic range (defined as the ratio of maximum signal possible to minimum detectable signal) of 100:1. Contacts 257A, 257B, 257C, 257D, 257E, and 257F provide individual contacts to detector elements 2051, 2052, 2053, 2054, 2055, and 2056 respectively, with a common contact to the bottom side of these detector elements achieved through contact 209D. Elements 2051, 2052, 2053, 2054, 2055, and 2056 form a one-dimensional imaging array. For low photon fluxes, the linear position-sensitive detector 203 will have poor resolution due to the low signal to noise of the PIN photodiode, and spatial resolution will be determined by the SSMCP detector array consisting of the detector elements 2051, 2052, 2053, 2054, 2055, and 2056. To provide higher position sensitivity, it is desirable to use spot size larger than the detector elements 2051, 2052, 2053, 2054, 2055, and 2056 and to use interpolation of spatial profile of the detected signal to determine the centroid of the incident photon flux 240. For high photon fluxes, some or all of the detector elements 2051, 2052, 2053, 2054, 2055, and 2056 will saturate, and the centroid of the incident flux can be determined by using the PIN photodiode 203 as a position-sensitive detector. Note that even though the single-photon detector elements 2051, 2052, 2053, 2054, 2055, and 2056 are saturated, they still provide a precise timing signal for detection of pulsed returns, which may also be used to gate the output of the position-sensitive detector formed from layer 203. Furthermore, note that the propagation of the detected signal in layer 203 results in a built-in delay as the signal propagates from the point of absorption to the contacts 255A, 255B, 256A, and 256B. This built-in delay may be used to facilitate gating of the signal in the position-sensitive detector formed in layer 203. This delay may also be used to facilitate the accuracy of the position sensitivity, because the delay time of the signal is dependent on the distance between the photogeneration point and the electrical contacts.

FIG. 2H shows an alternative embodiment where both the single-photon sensitive layer and the wide dynamic range layer are pixelated. Metalization layer 207E forms contacts to the single-photon sensitive pixels 252A, 252B, 252C, 252D, 252E and 252F, while metallization layer 207D forms contacts to both the bottom side of the single-photon sensitive layer 205C as well as to the top of the wide dynamic range layer 203, providing contacts to the wide dynamic range pixels 251A, 251B, 251C, 251D, 251E, 251F and 251G. Contact 253 forms a common contact to the bottom side of the wide dynamic range layer 203C. If substrate 201C is transparent, backside illumination may be used to illuminate the pixels, and flip chip bonding may be used to connect contacts 252A, 252B, 252C, 252D, 252E, 252F, 251A, 251B, 251C, 251D, 251E, 251F, 252G, and 253 to a readout circuit (ROIC); otherwise, the die should be front-side illuminated.

FIG. 2I shows an optical element 245 used to split the incident photon flux 260 between two separate detector arrays: a wide dynamic range detector array 275 and a single-photon sensitive detector array 276. In the figure, optical element 245 uses a spatial pattern of reflective and transmissive regions to reflect photons 262 to the wide dynamic range imaging array 275 and transmit photons 261 to the single-photon sensitive imaging array 276. Those of ordinary skilled in optics will recognize that alternative optical elements 245 may be used, including uniform partially reflective mirrors, diffractive beam splitters, etc. Other symmetries, such as swapping 275 and 276, are likewise anticipated.

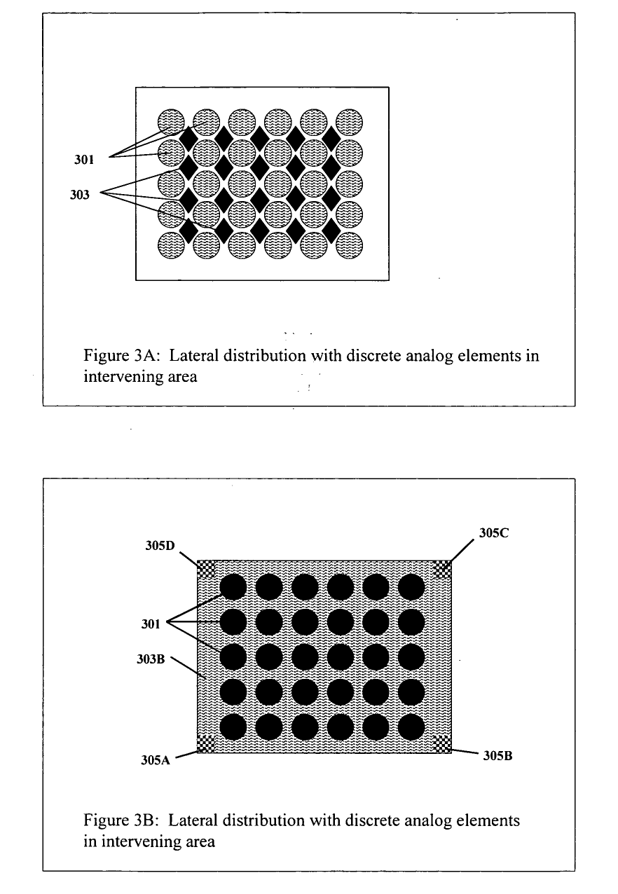

Reference is now made to FIG. 3A, showing an overhead view of an arrangement of pixels, where the wide dynamic range elements 303 occupy the dead space between single-photon sensitive elements 301.

In an illustrative embodiment, each single-photon sensitive element 301 is a Geiger mode APD and each of the wide dynamic range elements is a photoconductive detector. We note that each individual element 301 may be connected to an individual readout circuit, or the SSMCP arrangement may be used to connect a number of elements 301 together in parallel using integrated passive quench resistors and a common anode readout as described in HARMON, et. al, “Solid State Micro Channel Plate Photodetector”, patent application 2004/0245592 filed 1 May 2004, priority date 1 May 2003. Similarly, each element 303 may be connected individually, or may be connected in groups of parallel connected pixels to simplify the readout circuitry.

FIG. 3B shows a top-view of an arrangement of pixels, where the wide dynamic range element 303B is quasi-continuous and occupies most of the dead space between single-photon sensitive elements 301. In an illustrative embodiment, elements 301 are Geiger mode APDs connected in parallel in an SSMCP configuration, and element 303B has dual functionality, acting as a guard ring surrounding each Geiger mode element 301, and acting as a wide dynamic range photodiode. Corner contacts 305A, 305B, 305C, and 305D are used to provide a position-sensitive readout of element 303B. Those skilled in the art will recognize that the detector unit shown in FIG. 3B can be replicated to form an imaging array of pixels, and that contacts 305A, 305B, 305C, and 305D are four-fold redundant if position sensitivity is not required.

The figure may also be read conceptually to illustrate a particularly important embodiment of the invention fabricated as an array of photodiode pixels. A system wherein some of the pixels are capable of being operated in either avalanche gain mode 303B (with linear response but a dark noise current equivalent to hundreds of dark counts per pulse) or Geiger gain mode 301 (with sensitivity to single photons but no discrimination of 1 versus many photons in a pulse), such as APDs biased respectively below or above breakdown, can be conceptualized as analog islands in a sea of Geiger photodiodes, Geiger islands in a sea of analog photodiodes, or something in between. This embodiment gives access to more parameters and greater generality than the others for optimizing the balance between single-photon sensitivity and wide dynamic range. Key parameters include losses, noise equivalent power, detectivity, absorption, mean and expected variance of the irradiance level, pulse-pair resolution, accuracy, and precision, among others.

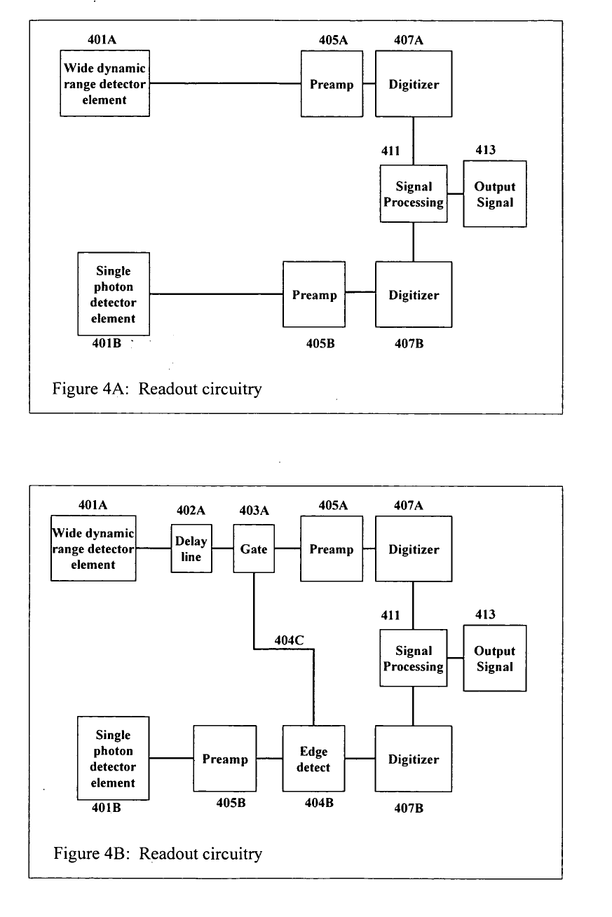

Reference is now made to FIG. 4A, showing a block diagram of the readout circuitry for each individual pixel element of the invention. Block 401A represents a wide dynamic range detector element, which is connected to a preamplifier 405A, whose output is connected through an optional digitizer 407A to a signal processor 411. Similarly, block 401B represents the single-photon sensitive detector element, which is connected to an optional preamplifer 405B, whose output is connected through an optional digitizer 407B to the signal processor 411. The signal processor 411 combines the signals from the wide dynamic range element 401A and the single-photon sensitive detector element 401B, using appropriate scale factors to account for the difference in gain of the two signals, and using techniques to linearize the signals, producing an output signal 413. Note that output encodings other than linear may be used instead, notably including a logarithmic encoding.

The circuitry will advantageously reside on a read-out integrated circuit (ROIC) coupled to the detector array to form a module with low parasitic capacitance between each pixel and a pre-amp. The ROIC will typically support functions of encoding and reporting out the signal; and setting and restoring bias voltage levels. It will advantageously also support processing, remapping, calibrating, correcting and/or adjusting the signal and bias voltages, whether controlled by circuitry on the ROIC, external circuitry, or both.

FIG. 4B shows another block diagram of a different readout circuit for each pixel element. In addition to the elements shown in FIG. 4A, FIG. 4B includes an edge detector 404B, which is used to detect the occurrence of a signal at detector 401B. The edge detector 404B provides a signal that triggers a gating circuit 403A, which is used to gate the signal from the wide dynamic range detector 401A. A delay line 402B is inserted between the gate circuitry 403A and the wide dynamic range detector element 401A to account for the delay caused by the amplification mechanism of the single-photon detector element 401B, the optional preamplifier 405B, the edge detector 404B, and the connection 404C.

We claim:

1. An extended dynamic range photodetector combining a plurality of single-photon sensitive detectors with a plurality of wide dynamic range photodetectors.

2. An extended dynamic range photodetector in accordance with claim 1 where the plurality of wide dynamic range photodetectors includes PIN photodiodes or PN photodiodes.

3. An extended dynamic range photodetector in accordance with claim 1 where the plurality of wide dynamic range photodetectors includes photoconductive detectors.

4. An extended dynamic range photodetector in accordance with claim 1 where the plurality of wide dynamic range photodetectors includes avalanche photodiodes operated in linear mode.

5. An extended dynamic range photodetector in accordance with claim 1 where the plurality of wide dynamic range photodetector elements includes charge-coupled devices.

6. An extended dynamic range photodetector in accordance with claim 1 where the plurality of wide dynamic range photodetector elements includes MSM detectors.

7. An extended dynamic range photodetector in accordance with claim 1 where the plurality of single-photon sensitive detectors includes avalanche photodiodes operated in Geiger mode.

8. An extended dynamic range photodetector in accordance with claim 1 where the plurality of single-photon sensitive detectors includes a plurality of multiplicity of arrays of single-photon sensitive detectors.

9. An extended dynamic range imaging detector in accordance with claim 1 where the plurality of single-photon sensitive detectors forms a multi-pixel array.

10. An extended dynamic range imaging detector in accordance with claim 1 where the plurality of wide dynamic range photodetectors forms a multi-pixel array.

11. An extended dynamic range imaging detector in accordance with claims 9 and 10 where the multi-pixel arrays interpenetrate.

12. An extended dynamic range imaging detector in accordance with claims 9 and 10 where the multi-pixel arrays overlap.

13. An extended dynamic range imaging detector in accordance with claims 9 and 10 where the multi-pixel arrays are formed from the same monolithic semiconductor wafer.

14. An extended dynamic range imaging detector in accordance with claim 1 where the wide dynamic range photodetector is position-sensitive.

15. A method of measuring the intensity of a beam of light striking a detector comprising the steps of
a. measuring some of the light with a plurality of photodetectors capable of resolving single-photon events, and
b. measuring some of the light with a plurality of photodetectors capable of measuring with a wide dynamic range but also having a lower limit on detectable signal that requires multiple photons.

16. The method of claim 15 where the measurements (a) and (b) occur mostly or completely simultaneously.

17. The method of claim 15 further including a step of reporting the measurements (a) and (b).

18. The method of claim 17 further including a step of calculating a function whose value depends on the values of the measurements (a) and (b).

19. The method of claim 15 further including an array of such detectors, where each detector acts as a pixel within the array.

20. The method of claim 19 further including a step of calculating a function whose value depends on the values of more than one pixel.
